(19) United States
(12) Patent Application Publication
(10) Pub. No.: US 2013/0271932 A1
(43) Pub. Date: Oct. 17, 2013

(54) ELECTRONIC DEVICE HAVING RECEIVER

(71) Applicants: TING-TING ZHAO, Shenzhen City (CN); HE-LI WANG, Shenzhen City (CN)

(72) Inventors: TING-TING ZHAO, Shenzhen City (CN); HE-LI WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/470,376

(22) Filed: May 14, 2012

(30) Foreign Application Priority Data
Apr. 12, 2012 (CN) 201210106059.X

(51) Int. Cl. H05K 5/03

(52) U.S. Cl. 361/752

(57) ABSTRACT

This invention provides an electronic device including a base defining a receiving space, a cover coupled to the base, a main circuit board retained within the receiving space, a control panel attached to the cover, and a receiver. The cover includes a positioning tab defining a cutout. The receiver includes a main body to convert remote signals into electrical signals and a plurality of pins parallelly connected to the main body. The main body is fixed within the cutout and the pins are connected in parallel to the control panel for transmitting the converted electrical signals to the main circuit board via the control panel.

### BACKGROUND

1. Technical Field

The present disclosure relates to an electronic device having a receiver.

2. Description of Related Art

Electronic devices, such as optical disk players, include a housing, a main circuit board adjacent to a bottom of the housing, and a receiver for receiving remote signals. The receiver is used to convert the received remote signal into electrical signals to be transmitted to the main circuit board. For receiving a larger range of remote signals, the receiver has often to be disposed higher than and far away from the main circuit board. Thus, it is inconvenient to assemble the receiver to the main circuit board.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an electronic device having a receiver in accordance to an exemplary embodiment.

FIG. 2 is an exploded, isometric view of the electronic device of FIG. 1.

FIG. 3 is an exploded, isometric view of the electronic device of FIG. 1, but viewed from a reverse perspective.

FIG. 4 is a cross-sectional view of the electronic device, cut along line IV-IV of FIG. 1.

### DETAILED DESCRIPTION

Embodiments of the present disclosure are described with reference to the accompanying drawings.

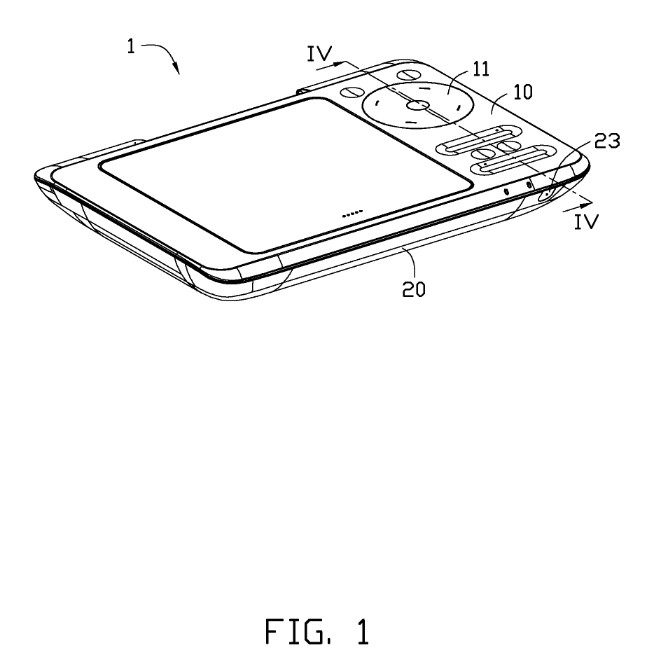

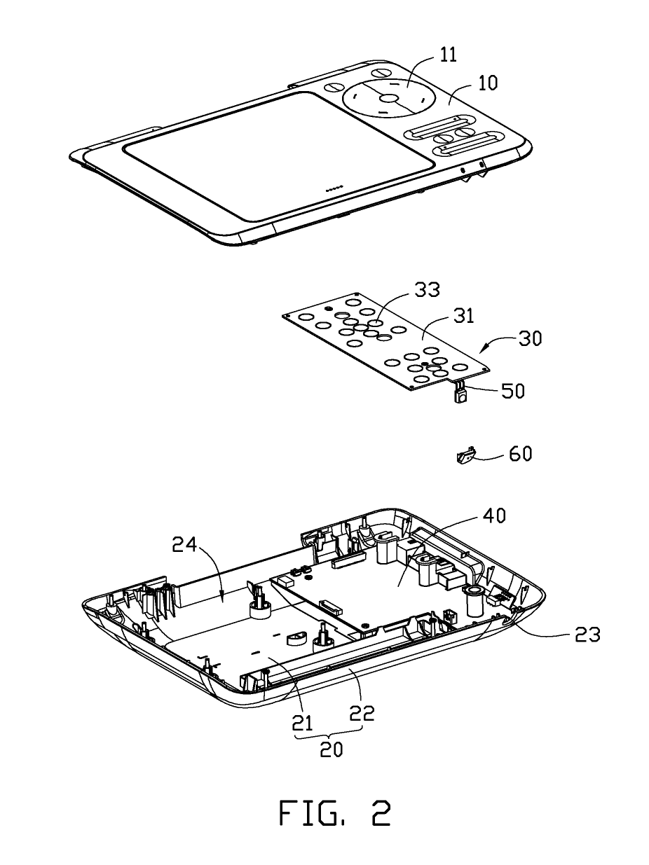

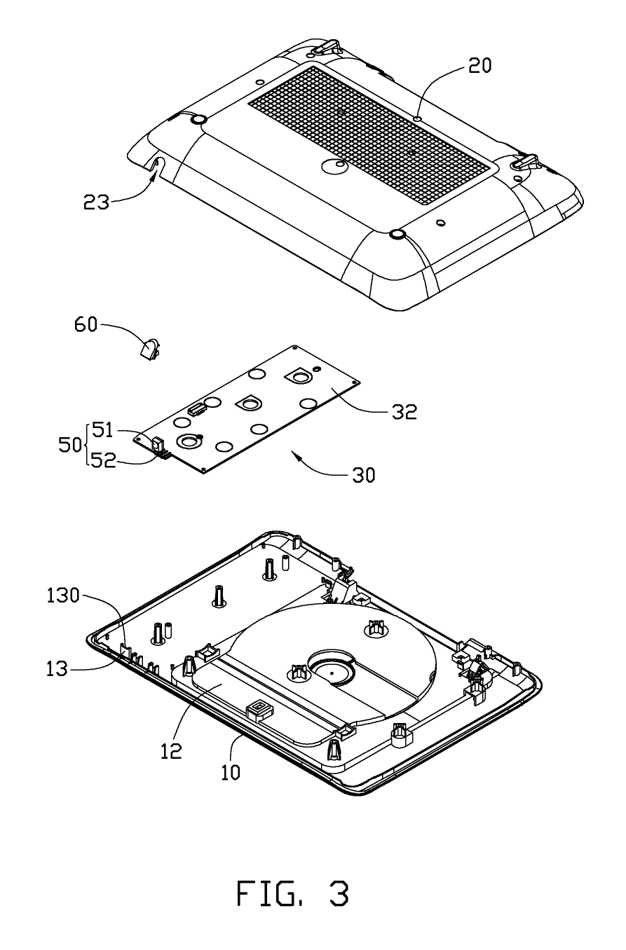

FIGS. 1-3 show an electronic device 1 according to an exemplary embodiment. The electronic device 1 includes a base 20, a cover 10 coupled to the base 20, a control panel 30 attached to the cover 10, a main circuit board 40 retained within the base 20, and a receiver 50 for receiving remote signals. In the exemplary embodiment, the electronic device 1 is an optical disc player and the receiver 50 is an infrared receiver.

The cover 10 includes a number of flexible keys 11 which can be depressed by a user. The cover 10 includes a connecting surface 12 facing the base 20 and a positioning tab 13 protruding perpendicularly from the connecting surface 12. The positioning tab 13 defines a cutout 130.

The base 20 includes a rectangular bottom plate 21 and four curved side plates 22 extending from the bottom plate 21, which cooperatively define a receiving space 24 therebetween for accommodating electronic components, such as the main circuit board 40. The base 20 defines a U-shaped flute 23 corresponding to the positioning tab 13 of the cover 10 in one of the side plates 22.

The control panel 30 includes a first surface 31 facing the cover 10 and an opposite second surface 32. The first surface 31 includes a number of dome-shaped switches 33 respectively staying in tight contact with the keys 11 of the cover 10. When the switch 33 is actuated by one key 11, the spring clip 31 generates an signal to the main circuit board 40 indicating that the corresponding key 11 is depressed.

The receiver 50 includes a main body 51 and three pins 5 connected in parallel to the main body 51. The main body 51 is configured to convert the received remote signals into electrical signals.

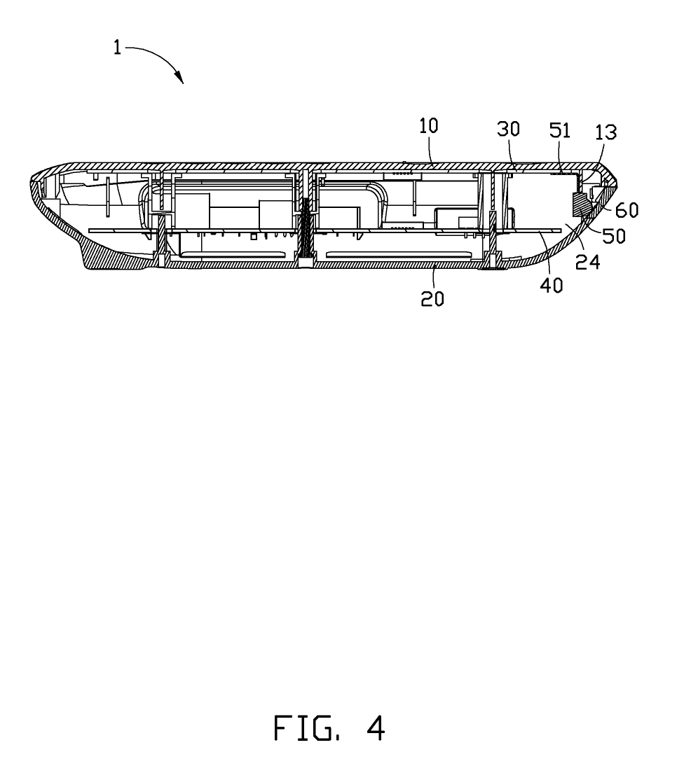

FIG. 4 shows after assembly, the main body 51 is fixed within the cutout 130 of the positioning tab 13. The pin 52 is deformed to stay in substantially tight contact with the positioning tab 13, and a distal end of the pin 51 is soldered in parallel with the second surface 32 of the control panel 30. Thus, the receiver 50 can transmit the electrical signals to the main circuit board 40 via the control panel 30. Also, it is convenient to assemble the receiver 50 into the electronic device 1, and the assembled receiver 50 is capable of receiving remote signals within a large range.

In the embodiment, the electronic device 1 further includes a window 60 securely retained within the flute 23 of the base 20 for protecting the receiver 50 and preventing dust from getting into the electronic device 1.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. An electronic device comprising:
a base defining a receiving space for accommodating electronic components;
a cover coupled to the base and comprising a positioning tab defining a cutout therein;
a main circuit board retained within the receiving space;
a control panel attached to the cover; and
a receiver comprising a main body to convert remote signals into electrical signals and a plurality of pins parallelly connected to the main body, wherein the main body is fixed within the cutout and the plurality of pins are parallelly connected to the control panel for transmitting the converted electrical signals to the main circuit board via the control panel.

2. The electronic device as described in claim 1, wherein the base comprises a rectangular bottom plate and four curved side plates protruding from the bottom plate, which cooperatively define the receiving space.

3. The electronic device as described in claim 1, wherein the base defines a flute corresponding to the positioning tab of the cover in one of the four side plates.

4. The electronic device as described in claim 1, further comprising a window securely retained within the flute.

5. The electronic device as described in claim 1, wherein the control panel comprises a plurality of dome-shaped switches capable of generating an electrical signal when being actuated.

6. The electronic device as described in claim 5, wherein the cover comprises a plurality of flexible keys staying in tight contact with the plurality of switches for actuating the plurality of switches.

7. The electronic device as described in claim 1, wherein the pin is deformed to stay in substantially tight contact with the positioning tab, and a distal end of each of the plurality of pins is soldered in parallel with the control panel.
